(19) United States
(12) Patent Application Publication
(10) Pub. No.: US 2016/0179202 A1
(43) Pub. Date: Jun. 23, 2016

(54) TOUCH DEVICE AND ELECTRONIC EQUIPMENT USING THE SAME

(71) Applicant: TIANJIN FUNAYUANCHUANG TECHNOLOGY CO.,LTD., Tianjin (CN)

(72) Inventors: PO-SHENG SHIH, New Taipei (TW); YU-JU HSU, New Taipei (TW); CHIEN-YUNG CHENG, New Taipei (TW); PIN-LUNG LIN, New Taipei (TW); MING-CHUN CHIU, New Taipei (TW)

(21) Appl. No.: 14/926,598

(22) Filed: Oct. 29, 2015

(30) Foreign Application Priority Data
Dec. 19, 2014 (CN) 201410791621.6

(51) Int. Cl. G06F 3/01; H05K 1/02; G06F 1/16; G06F 3/041

(52) U.S. Cl. CPC G06F 3/016; G06F 3/041; H05K 1/028; G06F 1/1613; G06F 2203/04102

(57) ABSTRACT

This disclosure is related to a touch device and electronic equipment using the same. The touch device includes a touch panel, a flexible printed circuit and a haptic feedback element. The touch panel includes a first surface and a second surface opposite to the first surface. The flexible printed circuit is electrically connected to the touch panel. The haptic feedback element is located on the flexible printed circuit or the touch panel.

### CROSS-REFERENCE TO RELATED APPLICATIONS

This application claims all benefits accruing under 35 U.S.C. §119 from China Patent Applications: Application No. 201410791621.6, filed on Dec. 29, 2014, in the China Intellectual Property Office, disclosures of which are incorporated herein by references.

### FIELD

The subject matter herein generally relates to touch devices and electronic equipments, especially touch devices with haptic feedback function and electronic equipments using the same.

### BACKGROUND

Different types of touch panels, including a resistance-type, a capacitance-type, an infrared-type and a surface sound wave-type have been widely utilized in electronic equipment using the same.

However, the touch panels are used to detect the touch signals and have no haptic feedback function. For example, the touch panel of the notebook is only used to control the mouse pointer of the notebook.

What is needed, therefore, is to provide a touch device with haptic feedback function and an electronic equipment using the same which can overcome the shortcomings as described above.

### BRIEF DESCRIPTION OF THE DRAWINGS

Implementations of the present technology will now be described, by way of example only, with reference to the attached figures, wherein:

FIG. 1 is a schematic view of a first embodiment of a touch device.

FIG. 2 is a schematic view of the touch device of FIG. 1 after a flexible printed circuit (FPC) is folded.

FIG. 3 is a photo view of a plurality of metal domes used in a touch device.

FIGS. 4-7 show different positions of a plurality of haptic feedback elements used in touch devices.

FIG. 8 is a schematic view of a second embodiment of a touch device.

FIG. 9 is a schematic view of a third embodiment of a touch device.

FIG. 10 is a schematic view of the touch device of FIG. 9 after a flexible printed circuit is folded.

FIG. 11 is a schematic view of a fourth embodiment of a touch device.

FIG. 12 is a schematic view of a fifth embodiment of a touch device.

FIG. 13 is a schematic view of the touch device of FIG. 12 after a flexible printed circuit is folded.

FIG. 14 is a schematic view of a sixth embodiment of a touch device.

FIG. 15 is a cross-sectional view along line XV-XV of FIG. 14.

FIG. 16 is a schematic view of a seventh embodiment of a touch device.

FIG. 17 is a schematic view of an eighth embodiment of a touch device.

FIG. 18 is a schematic view of one embodiment of a notebook utilizing the touch device of FIG. 1.

FIG. 19 is a schematic view of one embodiment of a notebook utilizing the touch device of FIG. 12.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

Several definitions that apply throughout this disclosure will now be presented.

The connection can be such that the objects are permanently connected or releasably connected. The term “outside” refers to a region that is beyond the outermost confines of a physical object. The term “inside” indicates that at least a portion of a region is partially contained within a boundary formed by the object. The term “substantially” is defined to be essentially conforming to the particular dimension, shape or other word that substantially modifies, such that the component need not be exact. For example, substantially cylindrical means that the object resembles a cylinder, but can have one or more deviations from a true cylinder. The term “comprising” means “including, but not necessarily limited to”; it specifically indicates open-ended inclusion or membership in a so-described combination, group, series and the like. It should be noted that references to “an” or “one” embodiment in this disclosure are not necessarily to the same embodiment, and such references mean at least one.

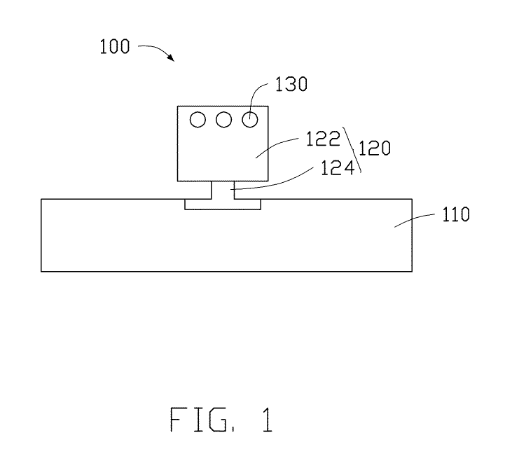

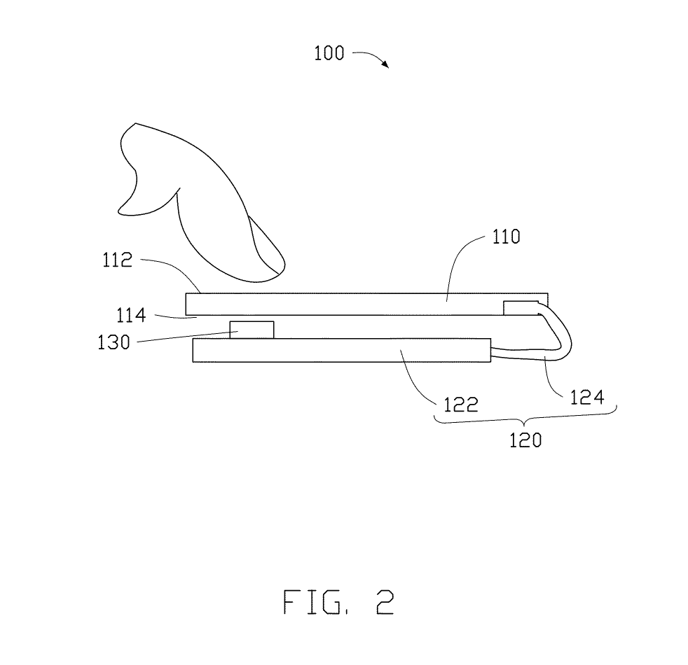

Referring to FIGS. 1-2, a touch device 100 of the first embodiment includes a touch panel 110, a flexible printed circuit 120 electrically connected to the touch panel 110, and a haptic feedback element 130 located on a surface of the flexible printed circuit 120.

The touch panel 110 can be any type such as capacitance-type, resistance-type, electromagnetic type, infrared type or hybrid type. The touch panel 110 can be transparent or opaque. The touch panel 110 has a first surface 112 and a second surface 114, opposite to the first surface 112. In use, the first surface 112 facing the user and is used as touch surface. In one embodiment, the touch panel 110 is a capacitance-type touch screen.

The flexible printed circuit 120 is configured to electrically connect the touch panel 110 to an integrated circuit (IC). The structure, size and shape of the flexible printed circuit 120 are not limited and can be designed according to need. The flexible printed circuit 120 includes a main portion 122 and a connecting portion 124, electrically connected to the main portion 122. The connecting portion 124 is configured to electrically connect the main portion 122 to the touch panel 110. The connecting portion 124 can be folded to form a U shape so that the main portion 122 and the touch panel 110 are substantially parallel with each other.

The haptic feedback element 130 is configured to respond to the pressure on the touch panel 110 by giving a haptic feedback. Thus, when the user presses the touch panel 110, the user can feel like pressing a key. The haptic feedback can be a passive feedback caused by the rebound of the haptic feedback element 130 or an active feedback caused by the vibration of the haptic feedback element 130 induced by an electrical signal. Furthermore, the haptic feedback element 130 can have a pressure detecting function. Thus, the electronic equipment using the touch device 100 can perform a corresponding function according to the pressure detected by the haptic feedback element 130.

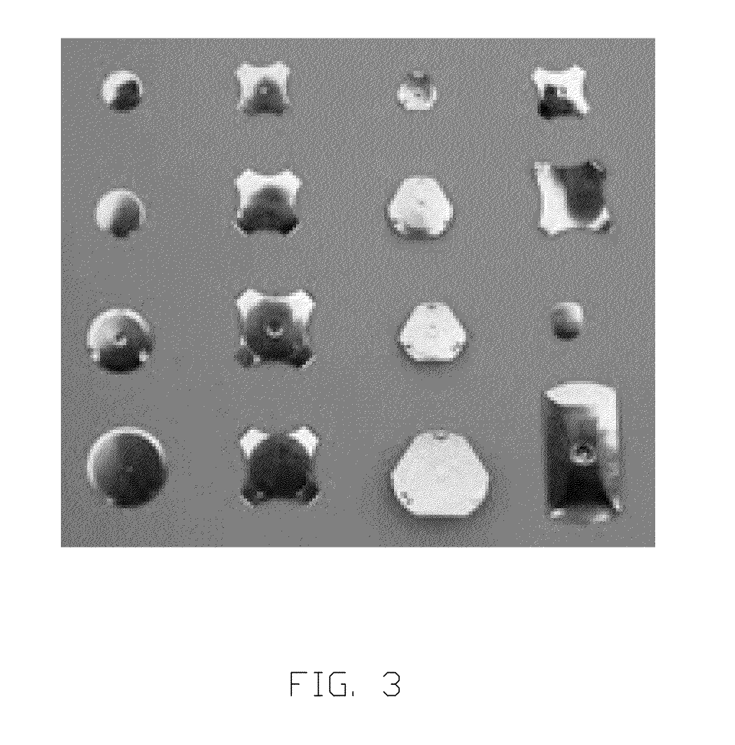

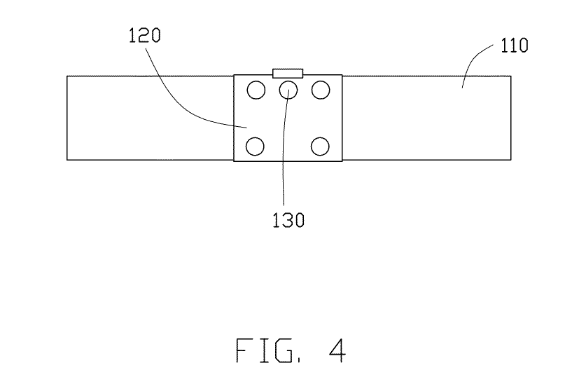

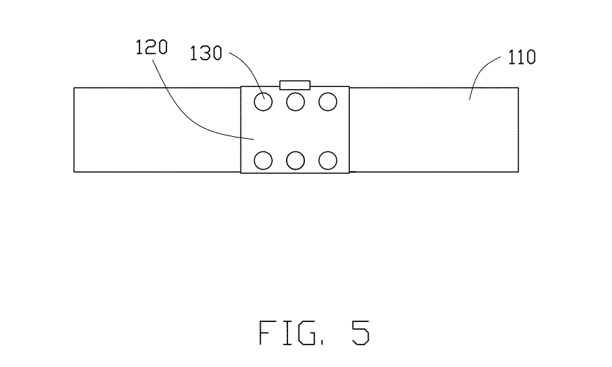

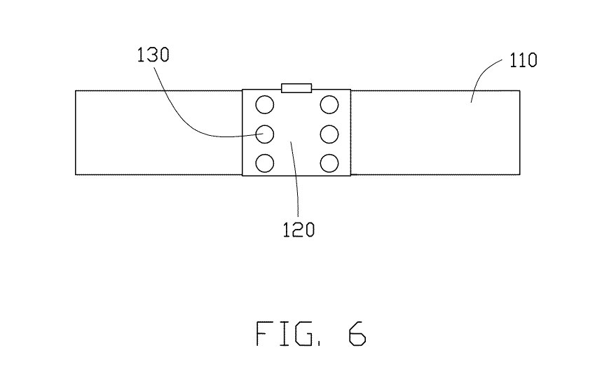

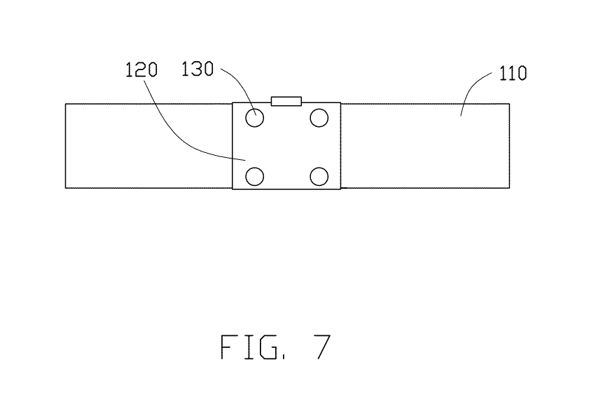

As shown in FIGS. 4-7, the plurality of haptic feedback elements 130 can be located anywhere of the main portion 122 as long as the plurality of haptic feedback elements 130 can be located at the target places after the flexible printed circuit 120 is folded. The haptic feedback element 130 can be fixed on the flexible printed circuit 120 by any methods such as welding, bonding by adhesive or one-batch forming. The structure, size, shape and type of the haptic feedback element 130 are not limited and can be designed according to need. The haptic feedback element 130 can be metal dome, metal spring, polymer block or vibrator. In one embodiment, the plurality of haptic feedback elements 130 are a plurality of metal domes. As shown in FIG. 3, the metal domes can have any shape as long as the metal domes can rebound after being bounded by pressing.

In one embodiment, the main portion 122 is spaced from the second surface 114 after the flexible printed circuit 120 is folded. The haptic feedback element 130 is located between the main portion 122 and the touch panel 110. The haptic feedback element 130 can be in direct contact with the second surface 114 of the touch panel 110. The haptic feedback element 130 can be fixed on the touch panel 110 by adhesive. When the user press the touch panel 110 at the pace corresponding to the haptic feedback element 130, the metal dome of the haptic feedback element 130 would be deformed and rebound to give a haptic feedback to the pressure. The haptic feedback of the metal dome is a passive haptic feedback.

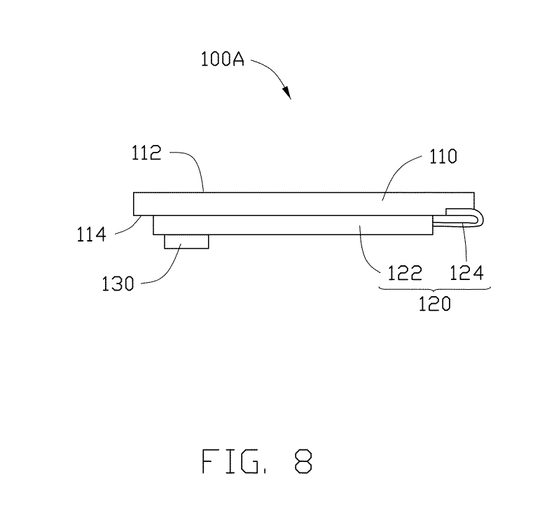

Referring to FIG. 8, a touch device 100A of the second embodiment is similar to the touch device 100 of the first embodiment above except that the main portion 122 is located between the touch panel 110 and the haptic feedback element 130 after the flexible printed circuit 120 is folded.

The main portion 122 of the flexible printed circuit 120 can be spaced from or in direct contact with the second surface 114 of the touch panel 110. When the main portion 122 of the flexible printed circuit 120 is spaced from the second surface 114, a support layer (not shown) can be located between the main portion 122 and the touch panel 110. Therefore, the pressure on the touch panel 110 can be acted on the feedback element 130. When the main portion 122 of the flexible printed circuit 120 is in direct contact with the second surface 114, the main portion 122 can be fixed on the touch panel 110 by adhesive. The main portion 122 can also be fixed on the second surface 114 of the touch panel 110 by a pressing force from a plate or element of the electronic equipment utilizing the touch device 100A.

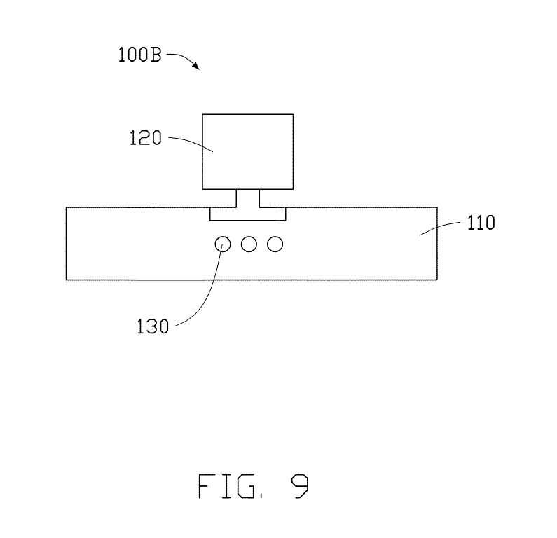

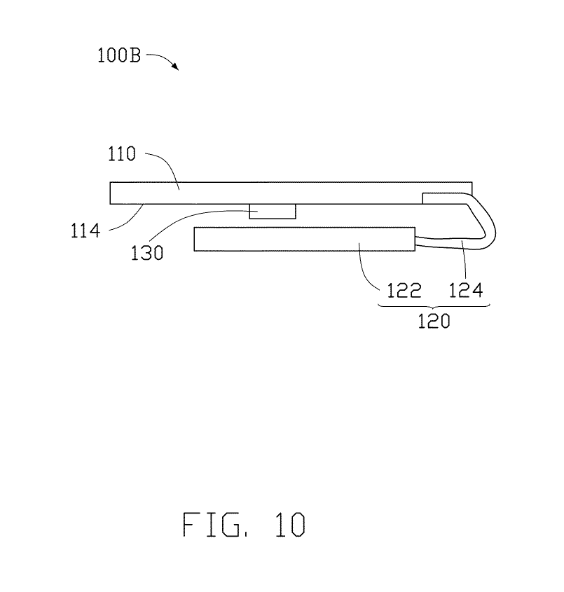

Referring to FIG. 9, a touch device 100B of the third embodiment is similar to the touch device 100 of the first embodiment above except that the haptic feedback element 130 is fixed on the second surface 114 by welding or adhesive. Therefore, the haptic feedback element 130 can be located between the touch panel 110 and the main portion 122 after the flexible printed circuit 120 is folded as shown in FIG. 10.

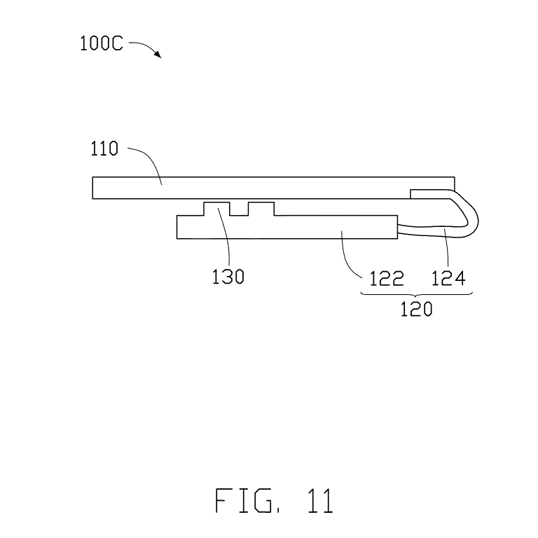

Referring to FIG. 11, a touch device 100C of the fourth embodiment is similar to the touch device 100 of the first embodiment above except that the haptic feedback elements 130 are bulges of a polymer layer of the flexible printed circuit 120. Thus, the haptic feedback elements 130 and the flexible printed circuit 120 are integrated. The bulges can be formed on both two opposite surfaces.

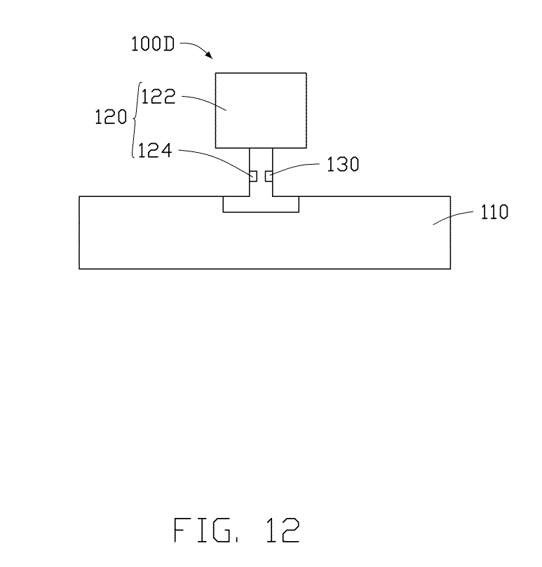

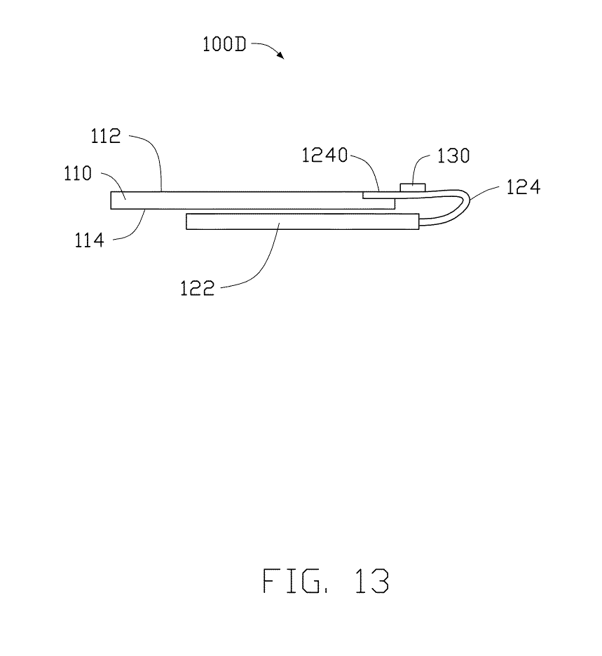

Referring to FIG. 12, a touch device 100D of the fifth embodiment is similar to the touch device 100 of the first embodiment above except that the haptic feedback elements 130 are located on a surface of the connecting portion 124 of the flexible printed circuit 120. As shown in FIG. 13, after the connecting portion 124 is folded, the connecting portion 124 has a flat surface 1240 substantially parallel with or coplanar with the first surface 112 of the touch panel 110. The haptic feedback elements 130 are located on the flat surface 1240. The main portion 122 can be spaced from and in direct contact with the second surface 114.

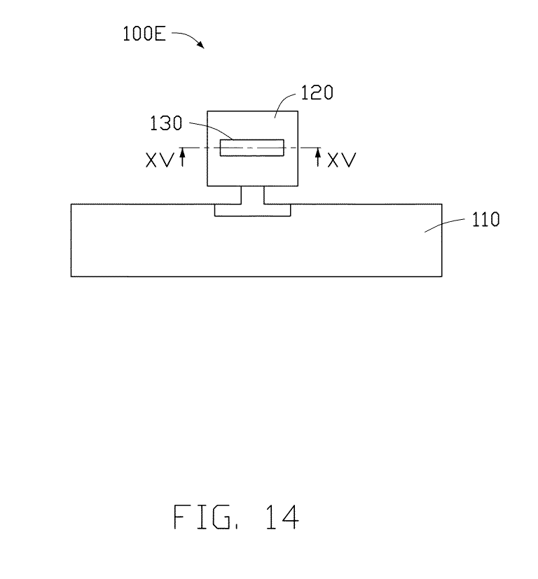

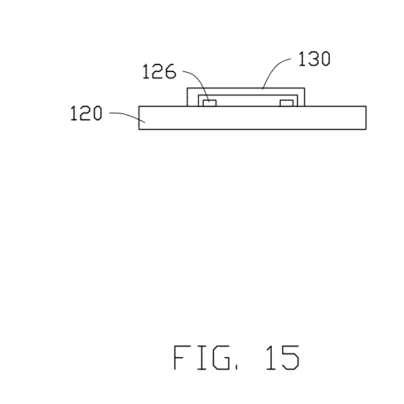

Referring to FIGS. 14-15, a touch device 100E of the sixth embodiment is similar to the touch device 100 of the first embodiment above except that the haptic feedback elements 130 can be electrically connected to the flexible printed circuit 120 when the haptic feedback element 130 is deformed. Thus, the integrated circuit electrically connected to the flexible printed circuit 120 can detect electrical signals.

In one embodiment, the haptic feedback element 130 is a curved metal sheet insulated from the flexible printed circuit 120 at a natural state. For example, the haptic feedback element 130 is an upside down U shape metal sheet. At least two conductive traces 126 of the flexible printed circuit 120 are partially located under, exposed to and spaced from the haptic feedback element 130. When the haptic feedback element 130 is deformed by pressure, the deformed haptic feedback element 130 can be in direct contact with the two conductive traces 126. Thus, the two conductive traces 126 are electrically connected to each other so that the integrated circuit electrically connected to the flexible printed circuit 120 can detect electrical signals of short-circuit and perform certain functions.

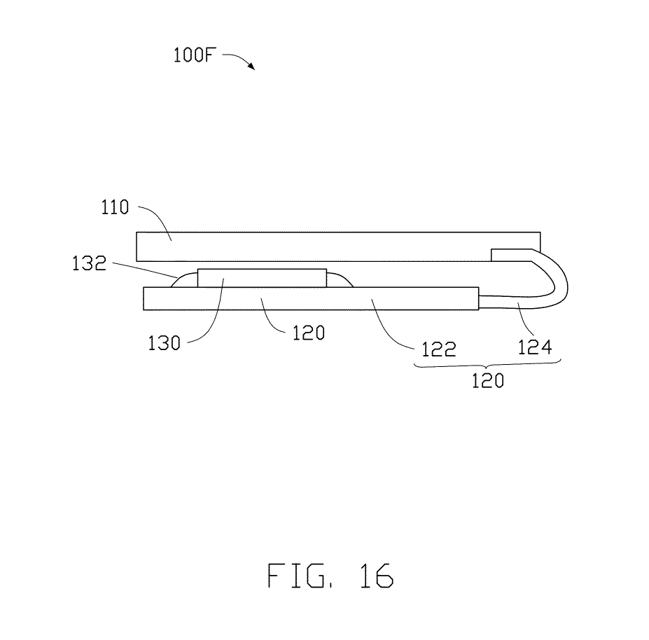

Referring to FIG. 16, a touch device 100F of the seventh embodiment is similar to the touch device 100 of the first embodiment above except that the haptic feedback element 130 is a vibrator electrically connected to the flexible printed circuit 120 by two conductive wires 132. The vibrator can be a piezoelectric vibrator, a membrane vibrator, or a haptic thread vibrator. The haptic feedback of the vibrator is an active haptic feedback.

The vibrator can vibrate under an electrical activation. The electrical activation can be performed by different modes. In one embodiment, when the touch panel 110 detects a touch signal, the integrated circuit electrically connected to the flexible printed circuit 120 can send an electrical activation signal to the haptic feedback element 130 via the flexible printed circuit 120. In another embodiment, when the user press the haptic feedback element 130 through the touch panel 110, the vibrator would be activated to vibrate by the pressure. In another embodiment, when the user press the haptic feedback element 130 through the touch panel 110, the piezoelectric vibrator would send an electrical signal to the integrated circuit electrically connected to the flexible printed circuit 120 due to the piezoelectric effect. The integrated circuit would judge the electrical signal from the piezoelectric vibrator and send an electrical activation signal to the haptic feedback element 130 according to the judgment.

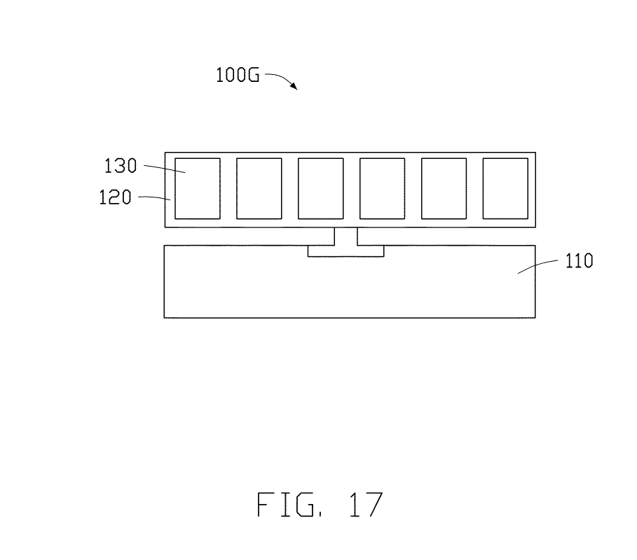

Referring to FIG. 17, a touch device 100G of the eighth embodiment is similar to the touch device 100 of the first embodiment above except that the flexible printed circuit 120 and the touch panel 110 substantially have the same size and shape, and the haptic feedback element 130 includes a plurality of membrane vibrators or membrane metal domes arranged to form an array.

The touch devices above can be used in electronic equipment such as mobile phone, tablet computer, notebook, game machine, or a learning machine. The notebooks using the touch devices above are provided below.

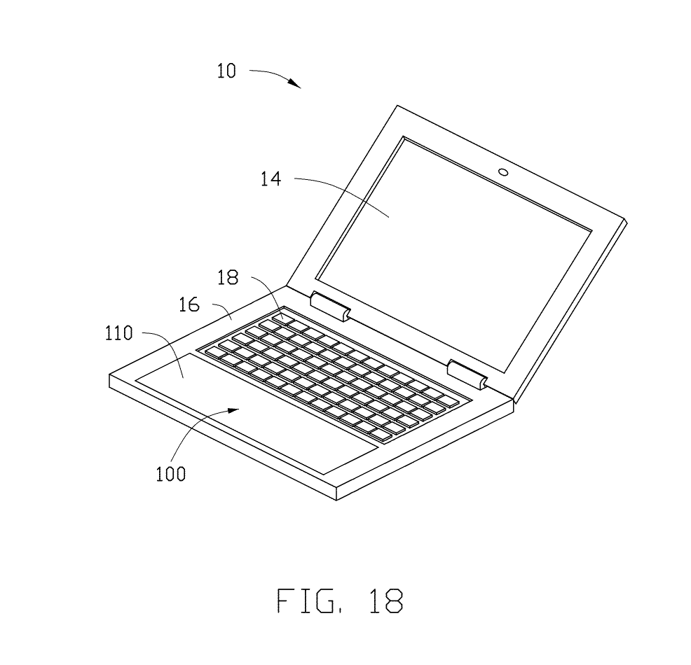

Referring to FIG. 18, a notebook 10 of one embodiment includes a main processor case 16, a display screen 14 connected to the main processor case 16, a keyboard 18 and the touch device 100 located on a surface of the main processor case 16.

The touch panel 110 of the touch device 100 is embedded on the main processor case 16 and exposed to outside of the main processor case 16. The flexible printed circuit 120 and the haptic feedback element 130 are located inside of the main processor case 16. The flexible printed circuit 120 and the haptic feedback element 130 can be supported by a plate or an inherent element of the main processor case 16.

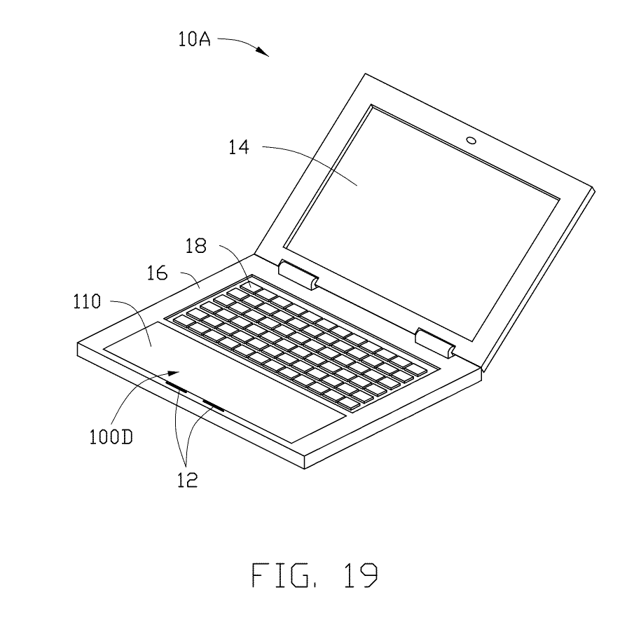

Referring to FIG. 19, a notebook 10A of another embodiment is similar to the notebook 10 of the embodiment above except that the touch device 100D of the fifth embodiment is used. Furthermore, two buttons 12 are located on bottom middle of the touch panel 110 and corresponds to the two haptic feedback elements 130 of the touch device 100D. The two buttons 12 are used as the left button and right button of the mouse. When user press the two buttons 12, the two haptic feedback elements 130 of the touch device 100D would give haptic feedbacks to the pressure. The notebook 10A can also have more than two buttons 12 as long as each button 12 is located corresponding to one of the haptic feedback elements 130 of the touch device 100D.

Because the haptic feedback element 130 is located on the flexible printed circuit 120 or the touch panel 110, the electronic equipment using the touch devices above does not need extra circuit board to support and electrically connect the haptic feedback elements 130 and have simple structure.

The embodiments shown and described above are only examples. Even though numerous characteristics and advantages of the present technology have been set forth in the forego description, together with details of the structure and function of the present disclosure, the disclosure is illustrative only, and changes may be made in the detail, including in matters of shape, size and arrangement of the parts within the principles of the present disclosure up to, and including, the full extent established by the broad general meaning of the terms used in the claims.

Depending on the embodiment, certain of the steps of methods described may be removed, others may be added, and the sequence of steps may be altered. The description and the claims drawn to a method may include some indication in reference to certain steps. However, the indication used is only to be viewed for identification purposes and not as a suggestion as to an order for the steps.

What is claimed is:

1. A touch device, comprising:
a touch panel, wherein the touch panel comprises a first surface and a second surface opposite to the first surface;
a flexible printed circuit electrically connected to the touch panel; and
a haptic feedback element located on the flexible printed circuit.

2. The touch device of claim 1, wherein the flexible printed circuit comprises a main portion and a connecting portion electrically connected to the main portion and the touch panel, and the haptic feedback element is located on the main portion.

3. The touch device of claim 2, wherein the connecting portion is folded so that the main portion and the touch panel are substantially parallel with each other; the main portion comprises a third surface facing the second surface and a fourth surface opposite to the third surface; and the haptic feedback element is located on the third surface.

4. The touch device of claim 2, wherein the connecting portion is folded so that the main portion and the touch panel are substantially parallel with each other; the main portion comprises a third surface facing the second surface and a fourth surface opposite to the third surface; and the haptic feedback element is located on the fourth surface.

5. The touch device of claim 1, wherein the flexible printed circuit comprises a main portion and a connecting portion electrically connected to the main portion and the touch panel, and the haptic feedback element is located on the connecting portion.

6. The touch device of claim 5, wherein the connecting portion is folded so that the main portion and the touch panel are substantially parallel with each other; the connecting portion comprises a fifth surface substantially parallel with the first surface; and the haptic feedback element is located on the fifth surface.

7. The touch device of claim 1, wherein the haptic feedback element and the flexible printed circuit are integrated.

8. The touch device of claim 7, wherein the haptic feedback element is a bulge of a polymer layer of the flexible printed circuit.

9. The touch device of claim 1, wherein the haptic feedback element is capable of being electrically connected to the flexible printed circuit when the haptic feedback element is deformed.

10. The touch device of claim 9, wherein the haptic feedback element is a curved metal sheet insulated from the flexible printed circuit at a natural state; at least two conductive traces of the flexible printed circuit are partially located under, exposed to and spaced from the haptic feedback element; when the haptic feedback element is deformed by a pressure, the haptic feedback element is capable of being in direct contact with the two conductive traces.

11. The touch device of claim 1, wherein the haptic feedback element is selected from the group consisting of metal dome, metal spring, and polymer block.

12. The touch device of claim 1, wherein the haptic feedback element is a vibrator electrically connected to the flexible printed circuit.

13. The touch device of claim 1, wherein the flexible printed circuit and the touch panel substantially have the same size and shape, and the haptic feedback element comprises a plurality of membrane vibrators or membrane metal domes arranged to form an array.

14. The touch device of claim 1, wherein the haptic feedback element is fixed on the flexible printed circuit by welding or bonding by adhesive.

15. A touch device, comprising:
a touch panel, wherein the touch panel comprises a first surface and a second surface opposite to the first surface;
a flexible printed circuit electrically connected to the touch panel; and
a haptic feedback element located on the flexible printed circuit or the touch panel.

16. The touch device of claim 15, wherein the flexible printed circuit comprises a main portion and a connecting portion electrically connected to the main portion and the touch panel; the connecting portion is folded so that the main portion and the touch panel are substantially parallel with each other; and the haptic feedback element is located between the touch panel and the main portion.

17. An electronic equipment comprising a touch device, wherein the touch device comprises:
a touch panel, wherein the touch panel comprises a first surface and a second surface opposite to the first surface;
a flexible printed circuit electrically connected to the touch panel; and
a haptic feedback element located on the flexible printed circuit or the touch panel.

18. The electronic equipment of claim 17, wherein the electronic equipment is a notebook; the notebook comprises a main processor case, a display screen connected to the main processor case, and a keyboard located on the main processor case; the touch panel is embedded on the main processor case and exposed to outside of the main processor case; and the flexible printed circuit and the haptic feedback element are located inside of the main processor case.

19. The electronic equipment of claim 18, wherein the flexible printed circuit comprises a main portion and a connecting portion electrically connected to the main portion and the touch panel; the connecting portion is folded so that the main portion and the touch panel are substantially parallel with each other; two haptic feedback elements are located on the connecting portion; and the notebook further comprises two buttons located on bottom middle of the touch panel and corresponds to the two haptic feedback elements.
